(19) United States
(12) Patent Application Publication
(10) Pub. No.: US 2014/0024161 A1
(43) Pub. Date: Jan. 23, 2014

(54) METHOD OF FABRICATING AN INERTIAL SENSOR

(71) Applicants: Stéphane Renard, Champ Sur Drac (FR); Antoine Filipe, La Tronche (FR); Joël Collet, Saint Martin D'uriage (FR)

(72) Inventors: Stéphane Renard, Champ Sur Drac (FR); Antoine Filipe, La Tronche (FR); Joël Collet, Saint Martin D'uriage (FR)

(73) Assignee: Tronic's Microsystems, Crolles (FR)

(21) Appl. No.: 14/001,799

(22) PCT Filed: Feb. 2, 2012
(86) PCT No.: PCT/FR2012/050236

§ 371 Date: Oct. 7, 2013

(30) Foreign Application Priority Data
Mar. 3, 2011 (FR) 1151746

(51) Int. Cl. B81C 1/00

(52) U.S. Cl. CPC B81C 1/00666
USPC 438/51

(57) ABSTRACT

An inertial sensor including at least one measurement beam and one active body formed of a proof body and of deformable plates, said active body being maintained in suspension inside of a tight enclosure via its plates, the measurement beam connecting a portion of the proof body to an internal wall of said enclosure, said measurement beam having a lower thickness than the proof body.

### BACKGROUND

The invention relates to the field of inertial sensors such as accelerometers or rate gyros, formed in MEMS (“microelectromechanical system”) or NEMS (“nanoelectromechanical system”) technology.

More specifically, the invention relates to a method for manufacturing an inertial beam measurement sensor of resonant type or having a variable resistance, for example, piezoresistive.

### STATE OF THE ART

An inertial sensor, such as an accelerometer, especially enables to measure the acceleration of an object on which it is placed. Such a sensor especially comprises a proof body (also called proof mass) coupled to one or several measurement beams. In a displacement of the sensor, an inertial force applies to the proof body and induces strain on the beam.

In the case of a resonator-type measurement beam, the strain applied by the mass of the proof body induces a variation of the resonator frequency. In the case of a measurement beam of variable resistance, for example, piezoresistive, the strain applied by the mass of the proof body induces a variation of the electric resistance. This enables to calculate the acceleration.

Generally, it is advantageous to use a proof body of high mass to maximize the inertial force during a displacement and thus to induce sufficient strain on the measurement beam. Further, it is also advantageous for the measurement beam to have the lowest possible thickness to maximize the strain applied by the proof body on this beam.

Document EP 2 211 185 discloses a sensor where the proof body has a larger thickness than the beam, and further provides two methods for manufacturing such a sensor based on an SOI (“Silicon On Insulator”) technology.

According to the first manufacturing method described in this document, the strain gauge is first etched in a surface layer of an SOI substrate, and then covered with a protection. A silicon epitaxy is then carried out on this surface layer to obtain a layer of desired thickness for the forming of the proof body. However, the epitaxial growth technique is heavy and expensive to implement and does not provide very large silicon layer thicknesses. Due to this limit, it is difficult to obtain an optimal sizing of the proof body, and thus of its mass, to maximize the strain applied to the gauge.

According to the second manufacturing method described in this document, the proof body is first etched in an SOI substrate. A polysilicon layer of nanometric thickness is then deposited for the forming of the strain gauge. However, the small thickness of polysilicon layers is still difficult to control, and their mechanical and electric properties are not as good as those of a single-crystal silicon layer. Further, the deposition of such a thin layer may be submitted to strain, such as deformations capable of affecting the gauge performance. It is thus difficult, with this method, to obtain a gauge having mechanical and electric features which optimize the sensor sensitivity.

Such solutions are thus not satisfactory, since a choice has to be made between a solution providing a strain gauge of low thickness to the detriment of the proof body mass, and a solution providing a proof body of significant mass to the detriment of the gauge sensitivity.

### SUMMARY

In such a context, the present invention especially aims at providing a novel inertial sensor manufacturing method free of the previously-mentioned limits. The invention especially aims at providing a manufacturing method enabling to optimize the dimensions of the proof body and of the strain gauge to improve the sensor performance. The invention especially aims at providing an inertial sensor having a better performance, comprising a strain gauge of lower thickness made of single crystal silicon, and a proof body of higher mass.

The invention thus aims at a method for manufacturing an inertial sensor, comprising at least:

the forming of at least one active body formed of a proof body and of deformable plates (for example, forming linear springs or torsion axes), by etching of a first active layer of a first substrate, said first active layer having a first thickness;

the forming of at least one measurement beam by etching of a second active layer of a second substrate, said second active layer having a second thickness lower than the first thickness;

the sealing of the first active layer to the second active layer;

the removal of the non-active layers of the first substrate; —the forming of a first cavity by etching of a third substrate;

the sealing of the third substrate to the active layer of the first substrate, the active body being arranged inside of the first cavity;

the removal of the non-active layers of the second substrate;

the forming of a second cavity by etching of a fourth substrate; and

the sealing of the fourth substrate to the active layer of the second substrate.

This method especially provides a better control of the dimensions of the beam and of the active body, and thus enables to optimize both the thickness of the active body and the beam thickness. The method especially enables to obtain measurement beams of very low thickness and an active body of higher mass. Further, the strain likely to deteriorate the measurement beam performance is limited all along the manufacturing process. Thereby, the measurement beam sensitivity is improved without limiting the mass of the proof body. In other words, the combination of a proof body having a high mass and of a measurement beam of low thickness provides a better sensitivity in terms of inertial measurement detection.

Advantageously, the method further comprises the forming of an electric contact between the active body and the measurement beam. For example, such an electric contact may be formed during the sealing of the first active layer to the second active layer, such a sealing enabling to form a mechanical contact and an electric contact between the beam and the active body.

According to an embodiment, the measurement beam is made of a piezoresistive material forming a strain gauge, the electric resistance of the material varying according to the strain applied to the mass.

According to another embodiment, the measurement beam is a mechanical resonator, the resonator frequency varying according to the strain applied to the mass. For example, the resonator comprises a vibrating plate, excitation means, and means for detecting the vibration.

For example, the ratio of the first thickness to the second thickness is greater than or equal to 5.

The manufacturing method may further comprise:

forming at least one recess crossing the thickness of the third substrate and emerging into the first substrate; and

depositing an electric contact point in said recess.

Preferably, the medium enclosing the measurement beam and the active body contains vacuum, to limit any degradation of the sensor resolution.

Preferably, all the sealings of the manufacturing method are performed under vacuum or under a controlled atmosphere. A sealing under vacuum is preferred for the forming of an inertial sensor provided with a resonator, and a sealing under controlled atmosphere is preferred for the forming of an inertial sensor provided with a piezoresistive strain gauge.

For example, the measurement beam is made of single-crystal silicon, advantageously doped to improve the sensitivity of the piezoresistive beam.

The proof mass may also be made of single-crystal silicon.

Advantageously, the first and second substrates are of SOI type.

The invention also aims at an inertial sensor comprising at least one measurement beam and one active body formed of a proof body and of deformable plates, said active body being maintained in suspension inside of a tight enclosure via its plates, and the measurement beam connecting a portion of the proof body to an internal wall of said enclosure, said measurement beam having a thickness lower than that of the proof body.

### BRIEF DESCRIPTION OF THE DRAWINGS

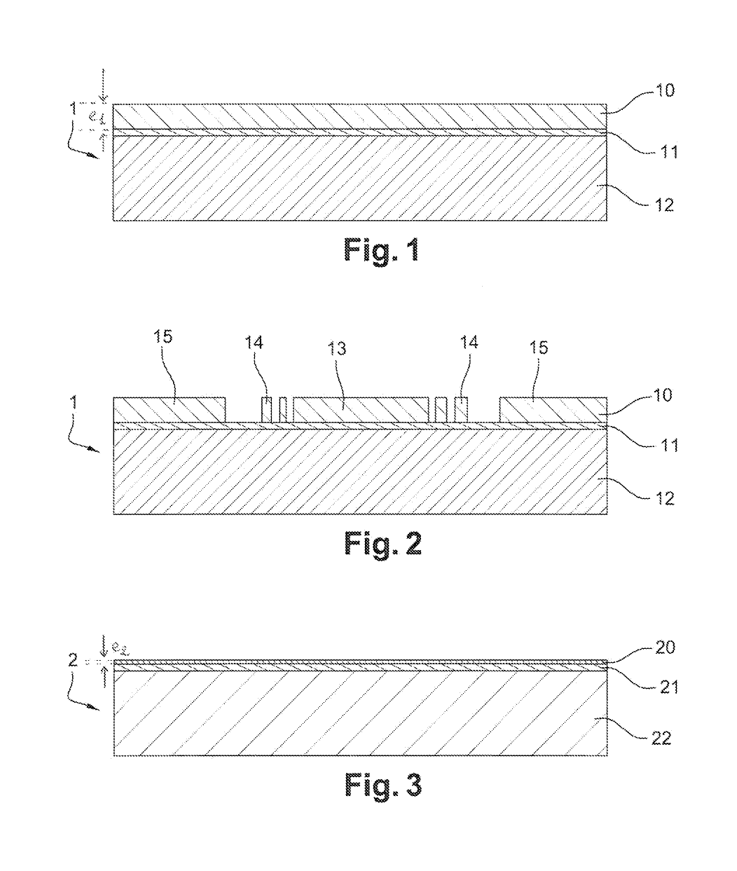

The foregoing and other features and advantages of the present invention will be discussed in detail in the following non-limiting description, in connection with the accompanying drawings, where FIGS. 1 to 15 are simplified views illustrating the steps of the method for manufacturing an inertial sensor according to an embodiment of the invention.

### DETAILED DISCUSSION OF A SPECIFIC EMBODIMENT

Referring to FIG. 15, a piezoresistive or resonant inertial sensor according to an embodiment of the invention especially comprises measurement beams 23 of piezoresistive or resonator type and an active body formed of a mobile proof body 13 and of deformable plates 14. Proof body 13 is maintained in suspension inside of a tight enclosure 30, 40, measurement beams 23 connecting the deformable plates to the internal wall of the enclosure. Measurement beams 23 especially have a lower thickness than proof body 13. Thus, in the case of a resonator-type measurement beam 23, the deflection of proof body 13 generates a variation of the resonator frequency and in the case of a piezoresistive strain gauge-type measurement beam 23, the deflection of proof body 13 induces the variation of the electric resistance of the gauge, which variation can be recovered via electric pads arranged within recesses.

The method for manufacturing such a sensor is described hereafter in relation with FIGS. 1 to 15.

Starting from a first substrate 1 (FIG. 1), which may be a wafer of SOI (“Silicon On Insulator”) material comprising a first active layer 10 having a first thickness e₁, for example, approximately ranging between 10 μm and 100 μm, and a non-active layer made of a layer of insulator 11 (for example, an oxide layer) and a support layer 12 (or bulk), an etching is performed in first active layer 10. This etching (FIG. 2), for example, of DRIE (“deep reactive ion etching”) type, comprises forming proof body 13 and deformable plates 14 in first active layer 10. In other words, the first active layer comprises proof body 13, deformable plates 14, and a frame 15.

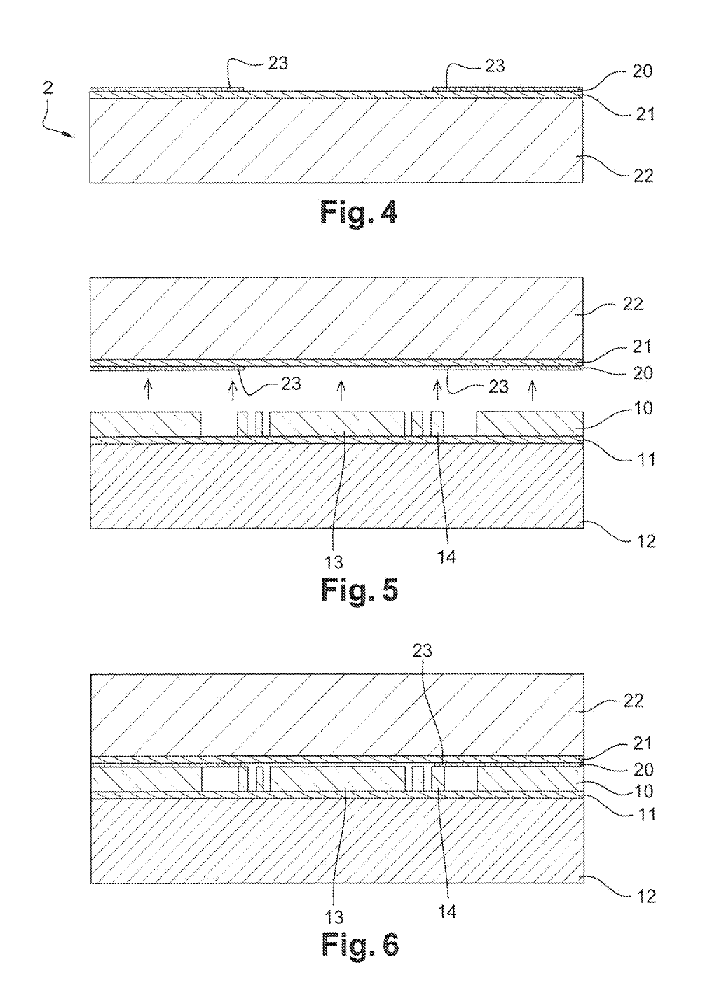

Starting from a second substrate 2 (FIG. 3), which may also be a layer of SOI-type material comprising a second active layer 20 having a second thickness e₂, for example, approximately ranging between 100 nm and 1 μm, and a non-active layer made of a layer of insulator 21 and a support layer 22, an etching is performed in first active layer 20. This etching (FIG. 4), for example, a photolithography, forms measurement beams 23 in second active layer 20.

First and second active layers 10, 20 are then sealed to obtain a mechanical sealing as well as an electric contact between the deformable plates and the measurement beams (FIGS. 5 and 6). In another configuration (not shown in the drawings), the measurement beams may be positioned between proof body 13 and frame 15. It is of course also possible to form this electric contact independently from the mechanical sealing between the two active layers 10, 20.

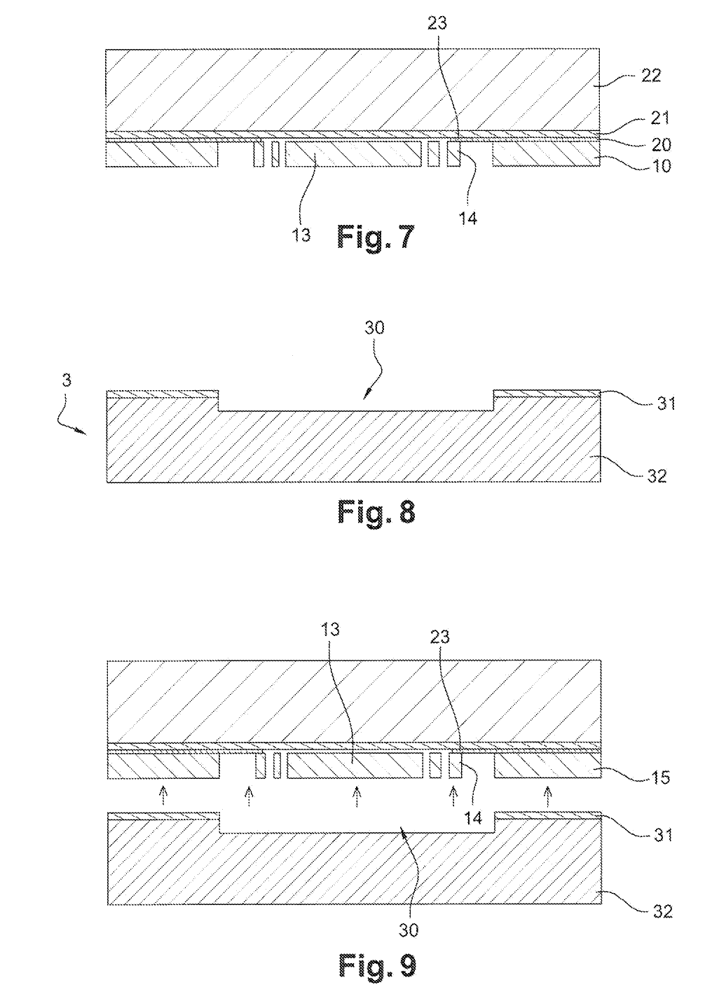

To disengage the active body and encapsulate it, the non-active layer, that is, insulating layer 11 and support layer 12, of the first substrate, is removed (FIG. 7). In other words, proof body 13 is in suspension and is maintained attached to second substrate 2 via measurement beams 23.

From a third substrate 3 (FIG. 8) especially comprising a layer 31 of insulator (for example, an oxide layer) and a support layer 32 (or bulk), a first cavity 30 enabling to contain the active body is formed, for example, by DRIE-type etching. For example, first cavity 30 is made in the insulator layer and a portion of the support layer, as illustrated in FIG. 8.

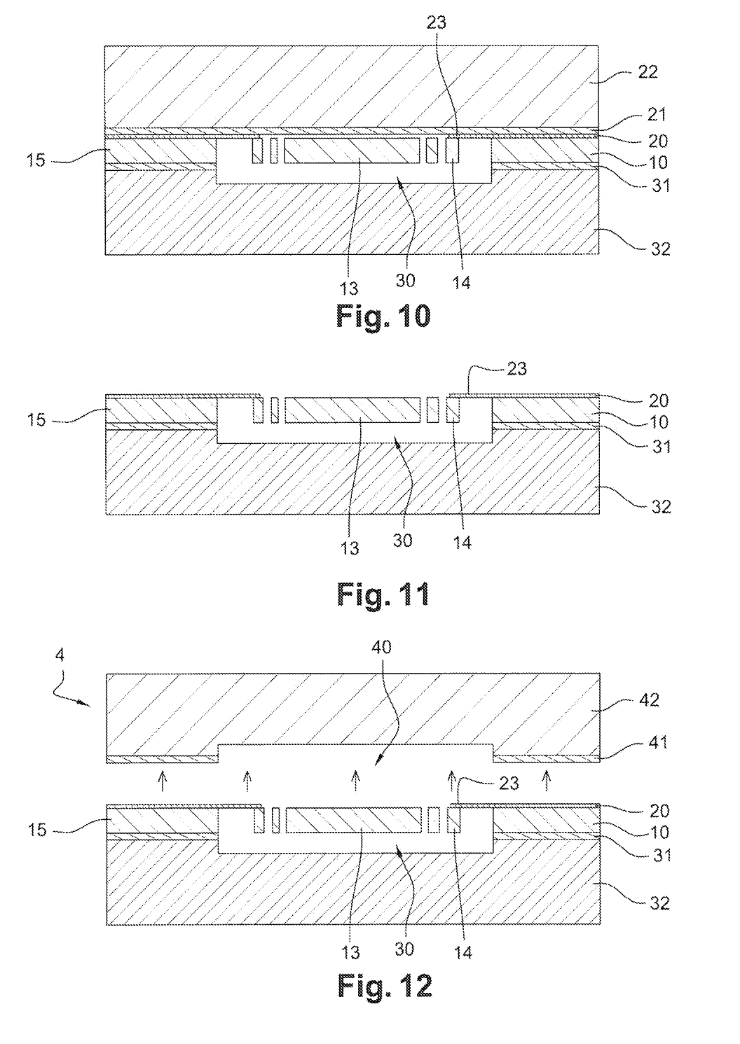

Third substrate 3 is then sealed (FIGS. 9 and 10) to the active layer of first substrate 1 so that the active body is inside of this first cavity 30. In other words, the free surface of insulating layer 31 of third substrate 3 is sealed to the free surface of frame 15 of the first active layer.

Similarly, the non-active layers, that is, insulating layer 21 and support layer 22, of second substrate 2 are removed (FIG. 11).

Starting from a fourth substrate 4 (FIG. 12) especially comprising a layer 41 of insulator (for example, an oxide layer) and a support layer 42 (or bulk), a second cavity 40 is also formed, for example, by DRIE-type etching. For example, second cavity 30 is made in the insulator layer and a portion of the support layer, as illustrated in FIG. 12.

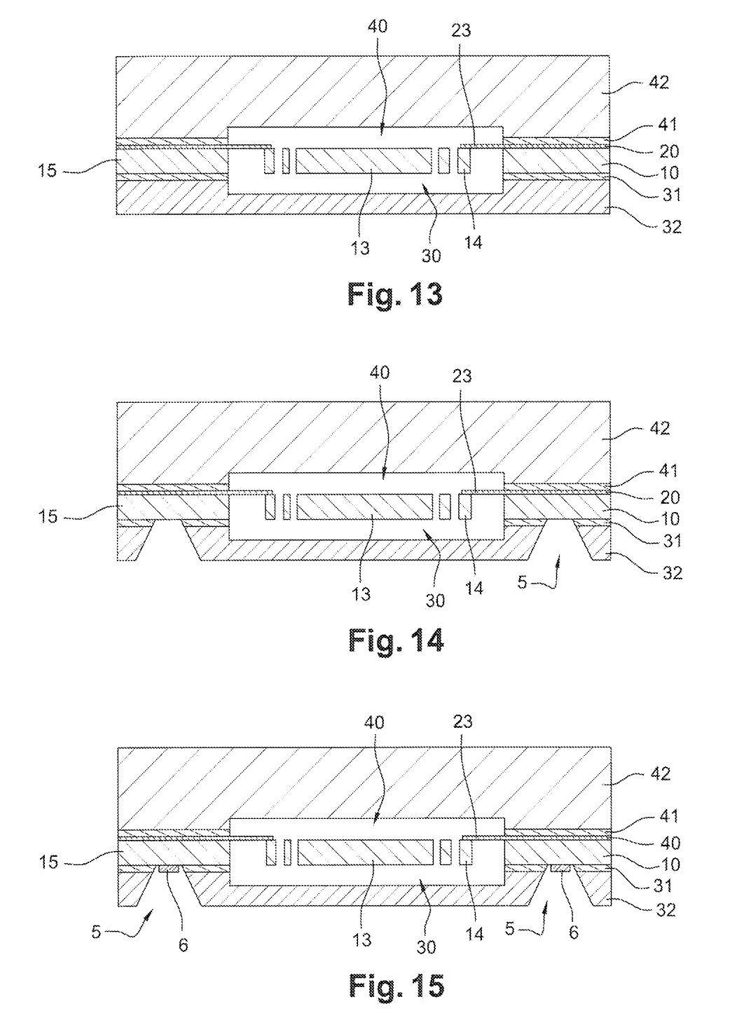

Fourth substrate 4 is then sealed (FIGS. 12 and 13) to the active layer of second substrate 2 so that the active body and the measurement beams are encapsulated within the tight enclosure formed by first and second cavities 30, 40.

Recesses crossing the thickness of third substrate 3 and emerging at the level of frame 15 of first substrate 1 may also be formed (FIG. 14). The depositing of an electric contact point 6 in these recesses enables to recover the electric signal generated during the deflection of proof body 13.

Thus, the manufacturing method of the invention especially enables to form inertial sensors especially provided with proof bodies of high mass combined with measurement beams of strain gauge or resonator type having a very low thickness, without altering the sensitivity of the assembly. In other words, the solution of the invention enables to optimize the dimensions of the proof body and of the measurement beams to improve the sensor performance. It is thus possible to obtain both a proof body of high mass to induce a high strain on the measurement beams, and measurement beams of very low thickness for a better detection sensitivity.

1. A method for forming an inertial sensor, comprising:
the forming of at least one active body formed of a proof body and of deformable plates, by etching of a first active layer of a first substrate, said first active layer having a first thickness;
the forming of at least one measurement beam by etching of a second active layer of a second substrate, said second active layer having a second thickness lower than said first thickness;
the sealing of the first active layer to the second active layer;
the removal of the non-active layers of the first substrate;
the forming of a first cavity by etching of a third substrate;
the sealing of the third substrate to the active layer of the first substrate, the active body being arranged inside of the first cavity;
the removal of the non-active layers of the second substrate;
the forming of a second cavity by etching of a fourth substrate; and
the sealing of the fourth substrate to the active layer of the second substrate.

2. The method of claim 1, further comprising the forming of an electric contact between the active body and the measurement beam.

3. The method of claim 2, wherein the electric contact is formed during the sealing of the first active layer to the second active layer, said sealing inducing both a mechanical contact and an electric contact between the beam and the active body.

4. The method of claim 1, wherein the measurement beam is made of a piezoresistive material forming a strain gauge.

5. The method of claim 1, wherein the measurement beam is a mechanical resonator.

6. The method of claim 1, wherein the ratio of the first thickness to the second thickness is greater than or equal to 5.

7. The method of claim 1, further comprising:
forming at least one recess crossing the thickness of the third substrate and emerging into the first substrate; and
depositing an electric contact point in said recess.

8. The method of claim 1, wherein a medium enclosing the measurement beam and the active body contains vacuum.

9. The method of claim 1, wherein all the sealings of the manufacturing method are performed under vacuum or under a controlled atmosphere.

10. The method of claim 1, wherein the measurement beam and the proof body are made of single-crystal silicon.

11. The method of claim 10, wherein the measurement beam is made of doped single-crystal silicon.

12. The method of claim 1, wherein the first and second substrates are of SOI type.
